(19) United States
(12) Patent Application Publication
(10) Pub. No.: US 2023/0207656 A1
(43) Pub. Date: Jun. 29, 2023

(54) GRAPHENE-SUPPORTED NOBLE-METAL COMPOSITE POWDER AND PREPARATION METHOD THEREOF, AND SCHOTTKY DEVICE

(71) Applicant: SHAANXI UNIVERSITY OF TECHNOLOGY, Hanzhong, Shaanxi (CN)

(72) Inventors: Hui Zhang, Hanzhong, Shaanxi (CN); Jinyu Duan, Hanzhong, Shaanxi (CN); Yapeng Li, Hanzhong, Shaanxi (CN); Junjun Feng, Hanzhong, Shaanxi (CN); Huiqi Wang, Hanzhong, Shaanxi (CN); Zhuolin Pu, Hanzhong, Shaanxi (CN); Yu Liu, Hanzhong, Shaanxi (CN)

(21) Appl. No.: 17/780,834

(22) PCT Filed: Jan. 12, 2022
(86) PCT No.: PCT/CN2022/071504

§ 371 Date: May 27, 2022

(30) Foreign Application Priority Data
Dec. 28, 2021 (CN) 202111626021.0

(51) Int. Cl. H01L 29/47; C01B 32/198; C01B 32/192; C01B 32/194; H01L 21/288

(52) U.S. Cl. CPC H01L 29/47; C01B 32/192; C01B 32/194; C01B 32/198; H01L 21/288; C01B 2204/22; C01P 2002/72; C01P 2004/03

(57) ABSTRACT

Disclosed are a graphene-supported noble-metal composite powder, a preparation method thereof, and a Schottky device. In the disclosure, graphene oxide and a noble metal precursor, as raw materials, are subjected to a hydrothermal reduction reaction to prepare the composite powder. In the process of the hydrothermal reduction reaction, graphene oxide and noble metal ions can be simultaneously reduced, and the formed noble metal nanoparticles are uniformly distributed on the surface and between layers of graphene, which effectively suppresses agglomeration of graphene, thereby fully exerting the electrical conductivity of graphene.

### CROSS REFERENCE TO RELATED APPLICATION

This patent application claims the benefit and priority of Chinese Patent Application No. 202111626021.0, entitled “Graphene-supported noble-metal composite powder and preparation method thereof, and Schottky device and preparation method thereof” filed on Dec. 28, 2021, the disclosure of which is incorporated by reference herein in its entirety as part of the present application.

### TECHNICAL FIELD

The present disclosure relates to the technical field of Schottky devices, in particular to a graphene-supported noble-metal composite powder and a preparation method thereof, and a Schottky device.

### BACKGROUND ART

Metal-semiconductor contact characteristics are widely used in semiconductor devices and integrated circuits. Any semiconductor device has a common basic structure, i.e., the input of energy and the output of functions after the operation of the device, and the hub responsible for this input and output is the metal-semiconductor contacts.

Schottky contact means that when a metal and a semiconductor material are in contact, the energy band of the semiconductor is bent at the interface to form a Schottky barrier. The Schottky junction is similar to the PN junction and has nonlinear impedance characteristics. However, compared with the PN junction, the Schottky junction has very low capacitance, to a few tenths of one picofarad, so it is commonly used in high-frequency circuits, especially in microwave, millimeter wave, and submillimeter wave circuit design. Schottky contact would affect the quality and reliability of semiconductor devices and integrated circuits, so it is necessary to study Schottky contact.

Graphene, which exhibits high electrical and thermal conductivity and has tunable band gap, two-dimensional structure, carrier mobility reaching 15000 cm² V⁻¹ s⁻¹, and quantum Hall effect at room temperature, has triggered a research upsurge. Further, due to semi-metal properties of graphene, Schottky heterojunctions are formed when graphene and semiconductors are contacted, which provides the possibility to replace metal electrodes with graphene, thereby reducing costs, saving resources, and improving device performance.

Existing studies have shown that contacting graphene with typical semiconductor materials such as Si, ZnO, GaN, Ge, GaAs, and CdSe, could further improve performance of devices such as photodetectors, light-emitting diodes, solar cells, metal-semiconductor field effect transistors, and sensors. However, there are van der Waals forces between graphene sheets, which are easy to agglomerate, resulting in a lower Schottky barrier height of the resulting device. For example, S. Tongay, et al. (S. Tongay, Graphite based Schottky diodes formed on Si, GaAs, 4 H-SiC substrate. 08 (2009) : 222103) used mechanical exfoliation to transfer graphene into semiconductor Si. The Schottky barrier height of graphene-Si contact was 0.4 eV, and the ideality factor was 1.25-2.0. Dhiraj Sinha and Ji Ung Lee et al. (Dhiraj Prasad Sinha, and Ji Ung Lee, Ideal Graphene/Silicon Schottky Junction Diodes.07 (2014): 1-14) transferred graphene prepared by chemical vapor deposition to semiconductor Si, and the Schottky barrier height of graphene-Si contact was 0.62 eV, and the ideality factor was 1.08.

In order to solve the problem that graphene is easy to agglomerate, researchers disperse noble metal nanoparticles between graphene layers, and suppress the agglomeration through the synergistic effect of noble metal nanoparticles and graphene, so as to better exert the excellent performance of graphene. Kun Huang (Kun Huang, Graphene coupled with Pt cubic nanoparticles for high performance, air-stable graphene-silicon solar cells. Nano Energy32 (2017) : 225-231) disclosed a graphene-silicon solar cell, in which platinum nanoparticles were prepared by hydrothermal method, graphene film was prepared by chemical vapor deposition (CVD) method, and graphene film was transferred to Si wafer by PMMA (polymethyl methacrylate), and platinum metal nanoparticle solution was applied onto the surface of graphene film. In this method, graphene and noble metal nanoparticles were prepared separately, and graphene was prepared by CVD method, which had a complicated preparation process, and high cost. The noble metal nanoparticles were unevenly dispersed between the graphene layers and the agglomeration of graphene also occurred easily.

### SUMMARY

An object of the present disclosure is to provide a graphene-supported noble-metal composite powder, a preparation method thereof, and a Schottky device. In the graphene-supported noble-metal composite powder according to the disclosure, the noble metal particles are uniformly dispersed, and the graphene is not easy to agglomerate. Also, the method for preparing the graphene-supported noble-metal composite powder is simple, and low in cost.

In order to achieve the above-mentioned object of the disclosure, the present disclosure provides the following technical solutions:

Disclosed is a method for preparing a graphene-supported noble-metal composite powder, comprising steps of
mixing a graphene oxide solution, a solution of a noble metal precursor, and a reducing agent, to obtain a mixed solution, the noble metal precursor comprising a noble metal present in the form of ions; and
subjecting the mixed solution to a hydrothermal reduction reaction, to obtain the graphene-supported noble-metal composite powder.

In some embodiments, the graphene oxide solution has a concentration of 1-2 mg/mL.

In some embodiments, the noble metal in the graphene-supported noble-metal composite powder is selected from the group consisting of aurum and platinum, and a mass ratio of the graphene oxide in the graphene oxide solution to the noble metal precursor in the solution of the noble metal precursor is in the range of 5 : 1 to 1 : 3.

In some embodiments, the noble metal precursor is at least one selected from the group consisting of chloroauric acid and chloroplatinic acid.

In some embodiments, the reducing agent comprises at least one selected from the group consisting of ascorbic acid, hydrazine hydrate, and sodium borohydride.

In some embodiments, mixing the graphene oxide solution, the solution of the noble metal precursor, and the reducing agent is performed by
adding the solution of the noble metal precursor to the graphene oxide solution and subjecting a resulting mixture to a first ultrasonic oscillation; and
adding ascorbic acid thereto, and subjecting a resulting mixture to a second ultrasonic oscillation, to obtain a mixed solution.

In some embodiments, the hydrothermal reduction reaction is performed at a temperature of 130-180° C. for 10-14 hours.

The present disclosure further provides a graphene-supported noble-metal composite powder prepared by the method as described in the above solutions, comprising graphene and noble metal nanoparticles supported on a surface and between layers of the graphene, the noble metal nanoparticles in the graphene-supported noble-metal composite powder accounting for 5-60 wt%.

The present disclosure also provides a Schottky device, comprising a semiconductor substrate and a coating of a composite powder on a surface of the semiconductor substrate, the composite powder being the graphene-supported noble-metal composite powder as described in the above technical solutions.

In some embodiments, the composite powder on the surface of the semiconductor substrate is present in an amount of 10-20 mg/cm².

The present disclosure also provides a method for preparing the Schottky device as described in the above technical solutions, comprising steps of
dispersing the graphene-supported noble-metal composite powder as described in the above technical solutions in an alcohol solvent, to obtain a composite powder dispersion; and
applying the composite powder dispersion onto a surface of a semiconductor, and drying, to obtain the Schottky device.

In some embodiments, the alcohol solvent is anhydrous ethanol.

In some embodiments, the composite powder dispersion has a composite powder concentration of 2-8 mg/mL.

The disclosure provides a method for preparing a graphene-supported noble-metal composite powder, comprising steps of mixing a graphene oxide solution, a solution of a noble metal precursor, and a reducing agent, to obtain a mixed solution, the noble metal precursor comprising a noble metal present in the form of ions; subjecting the mixed solution to a hydrothermal reduction reaction, to obtain the graphene-supported noble-metal composite powder. In the present disclosure, graphene oxide is used as raw material, and in the process of hydrothermal reaction, graphene oxide and noble metal ions could be reduced synchronously, and the formed noble metal nanoparticles are evenly distributed on the surface of graphene, which effectively suppresses the agglomeration of graphene, thereby fully exerting electrical conductivity of graphene. The method according to the disclosure has easily available raw materials, simple steps, and low cost.

Further, the method according to the present disclosure has good control flexibility, and could achieve the control of the doping concentration of the noble metal by adjusting the mass ratio of the graphene oxide to the noble metal precursor.

The present disclosure also provides the graphene-supported noble-metal composite powder prepared by the method as described in the above technical solutions, comprising graphene and noble metal nanoparticles supported on the surface and between layers of the graphene, the noble metal nanoparticles in the composite powder amounting for 5-60 wt%. The composite powder according to the present disclosure is not easy to agglomerate, exhibits good electrical conductivity, and could replace noble metal electrode materials. Also, the composite powder could be applied directly when used, without the transferring of the graphene film, nor separately preparing metal nanoparticles and graphene film for compositing, which is more convenient.

The present disclosure also provides a Schottky device, comprising a semiconductor substrate and a coating of a composite powder on a surface of the semiconductor substrate, the composite powder being the graphene-supported noble-metal composite powder as described in the above technical solutions. The Schottky device prepared from the graphene-supported noble-metal composite powder prepared in the present disclosure exhibits a higher Schottky barrier height, and a smaller ideality factor deviation from the theoretical value.

### BRIEF DESCRIPTION OF THE DRAWINGS

FIG. 1 shows the X-ray diffraction (XRD) pattern of the graphene-supported aurum nanoparticle composite powder as prepared in Example 1.

FIG. 2 is the scanning electron microscope (SEM) image of the graphene-supported aurum nanoparticles as prepared in Example 1, with a scale of 1 µm, and a magnification of 10000.

FIG. 3 shows the I-V characteristic curve of the Schottky device as prepared in Example 1.

FIG. 4 shows the XRD pattern of the graphene-supported platinum nanoparticle composite powder as prepared in Example 2.

FIG. 5 is the SEM image of the graphene-supported platinum nanoparticle composite powder as prepared in Example 2.

FIG. 6 shows the I-V characteristic curve of the Schottky device prepared in Example 2.

### DETAILED DESCRIPTION OF THE EMBODIMENTS

The disclosure provides a method for preparing a graphene-supported noble-metal composite powder, comprising steps of
mixing a graphene oxide solution, a solution of a noble metal precursor, and a reducing agent, to obtain a mixed solution, the noble metal precursor comprising noble metal present in the form of ions; and
subjecting the mixed solution to a hydrothermal reduction reaction, to obtain the graphene-supported noble-metal composite powder.

In the present disclosure, the graphene oxide solution, the solution of the noble metal precursor, and the reducing agent are mixed, to obtain a mixed solution. In some embodiments of the present disclosure, the graphene oxide has a diameter of 0.5-5 µm. In some embodiments, the graphene oxide has a thickness of 0.8-1.2 nm. In a specific embodiment of the present disclosure, the graphene oxide is purchased from Nanjing XFNANO materials Tech Co., Ltd., China. In some embodiments, the graphene oxide solution has a concentration of 1-2 mg/mL, and preferably 1.3-1.5 mg/mL. In some embodiments, a solvent in the graphene oxide solution is water, specifically distilled water. In some embodiments of the present disclosure, the graphene oxide solution is prepared by a process as follows: adding graphene oxide into water, and subjecting a resulting mixture to an ultrasonic dispersion, to obtain a graphene oxide solution. In some embodiments, the ultrasonic dispersion is performed for 2 hours.

In some embodiments of the present disclosure, the noble metal in the graphene-supported noble-metal composite powder is aurum or platinum. The noble metal is present in the form of ions in the noble metal precursor. In some embodiments, the noble metal precursor is chloroauric acid and/or chloroplatinic acid. In some embodiments, the chloroplatinic acid is specifically chloroplatinic acid hexahydrate. In some embodiments, a mass ratio of the graphene oxide in the graphene oxide solution to the noble metal precursor in the chloroauric acid solution is in the range of 5 : 1 to 1 : 3, and preferably 4 : 1 to 1 : 2. In a specific embodiment of the present disclosure, under the condition that the noble metal precursor is chloroauric acid, a mass ratio of the graphene oxide to chloroauric acid is 1 : 3; under the condition that the noble metal precursor is chloroplatinic acid hexahydrate, a mass ratio of the graphene oxide to chloroplatinic acid hexahydrate is 1 : 1. In the present disclosure, there is no special limitation on the concentration of the precursor solution, as long as the precursor solution could be dissolved. In a specific embodiment of the present disclosure, the chloroauric acid solution has a concentration of 5-15 mg/mL, and the chloroplatinic acid solution has a concentration of 1-15 mg/mL. In a specific embodiment of the present disclosure, chloroauric acid or chloroplatinic acid hexahydrate is added to distilled water, and the resulting mixture is sonicated for 5 min, to obtain a chloroauric acid solution or a chloroplatinic acid solution.

In some embodiments of the present disclosure, the reducing agent includes at least one selected from the group consisting of ascorbic acid, hydrazine hydrate, and sodium borohydride, more preferably ascorbic acid. Under the condition that ascorbic acid is used as the reducing agent, it is non-toxic and harmless and will not cause environmental pollution.

In some embodiments of the present disclosure, mixing the graphene oxide solution, the solution of the noble metal precursor, and the reducing agent is performed as follows: adding the solution of the noble metal precursor to the graphene oxide solution, subjecting a resulting mixture to a first ultrasonic oscillation, and adding ascorbic acid thereto, subjecting a resulting mixture to a second ultrasonic oscillation, to obtain a mixed solution. In some embodiments, the first ultrasonic oscillation is performed for 10 min. In some embodiments, the second ultrasonic oscillation is performed for 5 min.

In the present disclosure, after the mixed solution is obtained, the mixed solution is subjected to a hydrothermal reduction reaction, to obtain the graphene-supported noble-metal composite powder. In some embodiments of the present disclosure, the hydrothermal reduction reaction is performed at a temperature of 130-180° C., and preferably 140-160° C. In some embodiments, the hydrothermal reduction reaction is performed for 10-14 hours, and preferably 11-12 hours. In some embodiments, the hydrothermal reduction reaction is carried out in a reactor. In the process of the hydrothermal reduction reaction, the noble metal precursor is reduced to noble metal nanoparticles, and the graphene oxide is reduced to graphene.

In some embodiments, after the hydrothermal reduction reaction is completed, the obtained reaction solution is cooled to room temperature and filtered, to obtain a solid product; the solid product is repeatedly centrifugally washed with distilled water and alcohol, and then dried, to obtain the graphene-supported noble-metal composite powder.

The present disclosure also provides the graphene-supported noble-metal composite powder prepared by the method as described in the above technical solutions, comprising graphene and noble metal nanoparticles supported on the surface and between layers of the graphene, the noble metal nanoparticles in the composite powder accounting for 5-60 wt%. In some embodiments of the present disclosure, the noble metal nanoparticles are aurum nanoparticles and/or platinum nanoparticles, and preferably aurum nanoparticles or platinum nanoparticles. Under the condition that the noble metal nanoparticles are aurum nanoparticles, aurum nanoparticles in the composite powder accounts for 8-60%, and under the condition that the noble metal nanoparticles are platinum nanoparticles, aurum nanoparticles in the composite powder accounts for 6-53%. In the present disclosure, the noble metal nanoparticles are uniformly distributed between sheet layers of the graphene, which could prevent the agglomeration of the graphene, thereby improving the electrical conductivity of the graphene.

The present disclosure also provides a Schottky device, comprising a semiconductor substrate and a coating of a composite powder on a surface of the semiconductor substrate, the composite powder being the graphene-supported noble-metal composite powder as described in the above technical solutions. In some embodiments of the present disclosure, the composite powder on the surface of the semiconductor substrate is present in an amount of 10-20 mg/cm², and preferably 13-18 mg/cm². Under the condition that the composite powder according to the present disclosure is used to prepare a Schottky device, in which graphene is not easy to agglomerate, the prepared Schottky device exhibits high barrier height, and a smaller ideality factor deviation.

The present disclosure also provides a method for preparing the Schottky device as described in the above technical solutions, comprising steps of
dispersing the graphene-supported noble-metal composite powder as described in the above technical solutions in an alcohol solvent, to obtain a composite powder dispersion; and
applying the composite powder dispersion onto a surface of a semiconductor, and drying, to obtain the Schottky device.

In the present disclosure, the graphene-supported noble-metal composite powder as described in the above technical solutions is dispersed in an alcohol solvent, to obtain a composite powder dispersion. In some embodiments of the present disclosure, the alcoholic solvent is anhydrous ethanol. In some embodiments, the composite powder dispersion has a composite powder concentration of 2-8 mg/mL. In a specific embodiment of the present disclosure, the composite powder was added to an alcohol solvent, and the resulting mixture is then subjected to an ultrasonic oscillation for 2 hours, to obtain the composite powder dispersion. In the present disclosure, unless otherwise specified, the ultrasonic oscillation is performed at room temperature.

After the composite powder dispersion is obtained, the composite powder dispersion is applied onto a surface of a substrate, and dried, to obtain the Schottky device. In some embodiments of the present disclosure, the semiconductor is a silicon wafer. In some embodiments, the silicon wafer is cleaned with alcohol under an ultrasonic condition, to remove impurities on the surface. In some embodiments, the applying is performed by spin coating. In a specific embodiment of the present disclosure, the amount of the composite powder on the surface of the semiconductor is controlled by repeating the process of “applying-drying”. The wet coating is dried after each application, and another application is performed. The operations of “applying-drying” is repeated until the amount of the composite powder on the semiconductor surface reaches the requirement. In some embodiments, the drying is performed at 50° C. In some embodiments, the drying is performed for 5-10 min each time. In a specific embodiment of the present disclosure, the process of applying-drying is repeated for 20 times.

Technical solutions according to the present disclosure will be described in detail below in conjunction with the examples, but they should not be construed as limiting the scope of the present disclosure.

### Example 1

(1) 50 mg of graphene oxide was ultrasonically dispersed in 50 mL of distilled water by sonicating for 2 hours, and a 1 mg/mL graphene oxide solution was prepared.

(2) 150 mg of chloroauric acid was added to 10 mL of distilled water, and the resulting mixture was sonicated for 5 min, obtaining a chloroauric acid solution.

(3) The chloroauric acid solution was poured into the graphene oxide solution, and the resulting mixture was subjected to an ultrasonic oscillation for 10 minutes. 100 mg of ascorbic acid was then added thereto, and the resulting mixture was subjected to an ultrasonic oscillation for 5 minutes, obtaining a mixed solution.

(4) The mixed solution prepared in step (3) was added into a hydrothermal reactor, heated to 160° C., and maintained at the temperature for 12 hours. The resulting reaction mixture was cooled to room temperature, centrifugally washed with distilled water and alcohol for 6 times, and dried at 70° C., obtaining graphene-supported aurum nanoparticle composite powder.

(5) The silicon wafer (with a size of 1 cm × 1 cm, and a coating area of 0.5 cm × 1 cm) was repeatedly cleaned with alcohol under an ultrasonic condition to remove impurities on the surface. 20 mg of the composite powder prepared in step (4) was added to 5 mL of anhydrous ethanol, and the resulting mixture was subjected to an ultrasonic oscillation for 2 hours, obtaining a 4 mg/mL dispersion. The dispersion was then applied onto a silicon wafer by spin coating, and dried at 50° C. after each spin coating. The applying-drying operation was repeated for 20 times (each application in an amount of about 0.125-0.25 mL), obtaining the Schottky device.

(6) The I-V characteristic curve of the Schottky device prepared in step (5) was tested by using the instrument KEYSIGHT B2901A. An indium foil was placed on the silicon side, and two probes were placed on the silicon side, and the graphene-supported aurum nanoparticle side respectively. The test was performed at a voltage ranging from -1 V to 1 V, and at a temperature of 300 K.

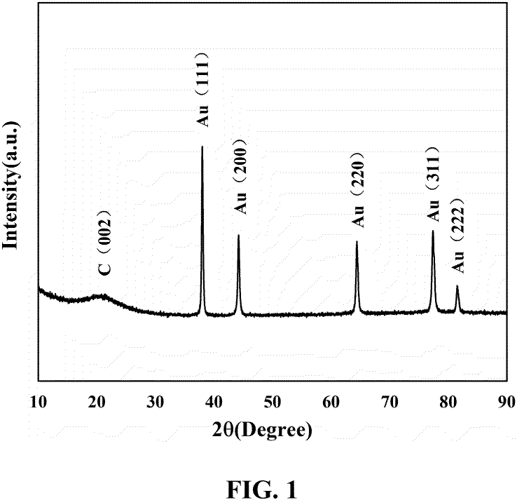

FIG. 1 shows the XRD pattern of the obtained graphene-supported aurum nanoparticle composite powder. It can be seen from FIG. 1 that the diffraction peaks at 38.1°, 44.5°, 64.5°, 77.5°, 81.7° are in agreement with peaks assigned to crystal planes of (111), (200), (220), (311) and (222) of the Au face-centered cubic crystal structure. The diffraction peak at 21° is assigned to C (002), which is the characteristic diffraction peak of graphene.

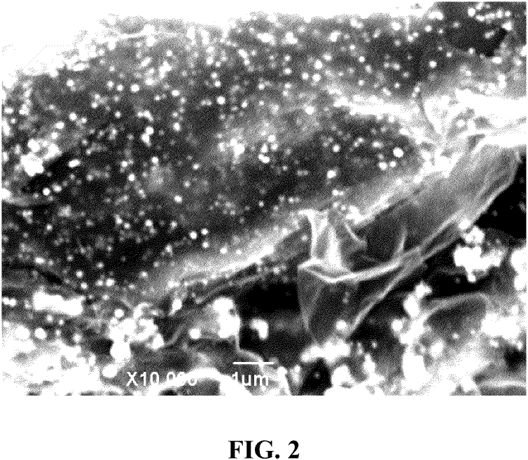

FIG. 2 is the SEM image of the obtained graphene-supported aurum nanoparticles, with a scale of 1 µm, and a magnification of 10000. As can be seen from FIG. 2, the aurum nanoparticles were more uniformly distributed on the surface and between the layers of graphene; the graphene was in a transparent layered structure with wrinkles at the edges, and a small amount of agglomerated aurum nanoparticles is present.

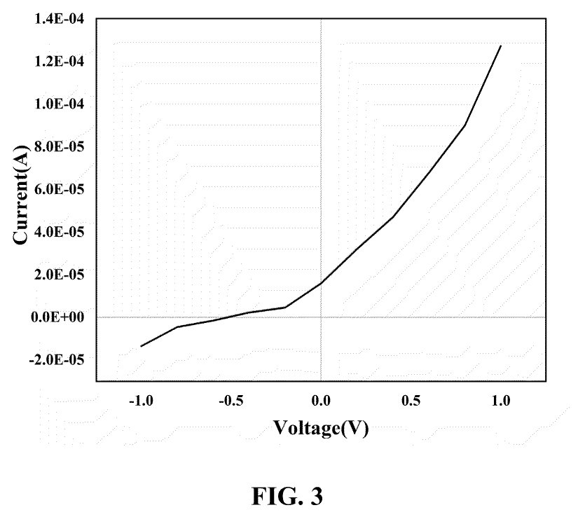

FIG. 3 shows the I-V characteristic curve of the Schottky device. As can be seen from FIG. 3, the current at the forward voltage of 1 V is 1.27E-4, the Schottky barrier height is 0.613 eV, and the ideality factor is 1.7.

### Example 2

(1) 50 mg of graphene oxide was ultrasonically dispersed in 50 mL of distilled water by sonicating for 2 hours, and a 1 mg/mL graphene oxide solution was prepared.

(2) 50 mg of chloroplatinic acid hexahydrate was added to 10 mL of distilled water, and the resulting mixture was sonicated for 5 min, obtaining a chloroplatinic acid solution.

(3) The chloroplatinic acid solution was poured into the graphene oxide solution, and the resulting mixture was subjected to an ultrasonic oscillation for 10 minutes. 100 mg of ascorbic acid was then added thereto, and the resulting mixture was subjected to an ultrasonic oscillation for 5 minutes, obtaining a mixed solution.

(4) The mixed solution prepared in step (3) was added into a hydrothermal reactor, heated to 160° C., and maintained at the temperature for 12 hours. The resulting reaction mixture was cooled to room temperature, centrifugally washed with distilled water and alcohol for 6 times, and dried at 70° C., obtaining graphene-supported platinum nanoparticle composite powder.

(5) The silicon wafer was repeatedly cleaned with alcohol under an ultrasonic condition to remove impurities on the surface. 20 mg of the above composite powder was added to 5 mL of anhydrous ethanol, and the resulting mixture was subjected to an ultrasonic oscillation for 2 hours, obtaining a 4 mg/mL dispersion. The dispersion was then applied onto a silicon wafer by spin coating, and dried at 50° C. after each spin coating. The applying-drying operation was repeated for 20 times, obtaining the Schottky device. In this example and subsequent examples, the size of the silicon wafer used, the amount for each application were the same as those in Example 1.

(6) The I-V characteristic curve of the Schottky device was tested by using the instrument KEYSIGHT B2901A. An indium foil was placed on the silicon side, and two probes were placed on the silicon side and the graphene-supported platinum nanoparticle side respectively. The test was performed at a voltage ranging from -1 V to 1 V, and at a temperature of 300 K.

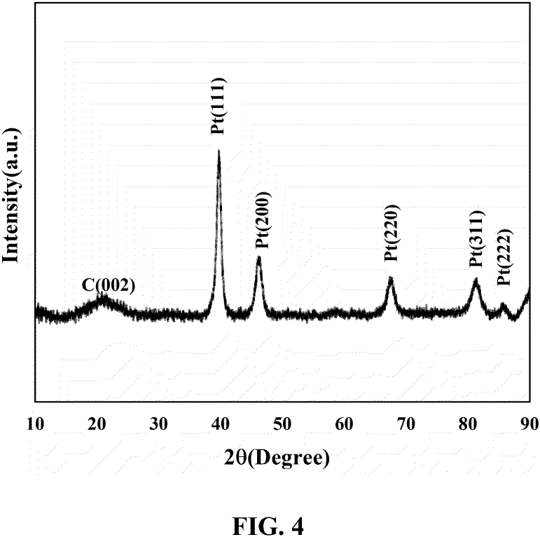

FIG. 4 shows the XRD pattern of the obtained graphene-supported platinum nanoparticle composite powder. It can be seen from FIG. 4 that the diffraction peaks at 39.89°, 46.40°, 67.70°, 81.57°, 86.03° are in in agreement with peaks assigned to crystal planes (111), (200), (220), (311) and (222) of the Pt face-centered cubic crystal structure. The diffraction peak at 21° is assigned to C (002), which is the characteristic diffraction peak of graphene.

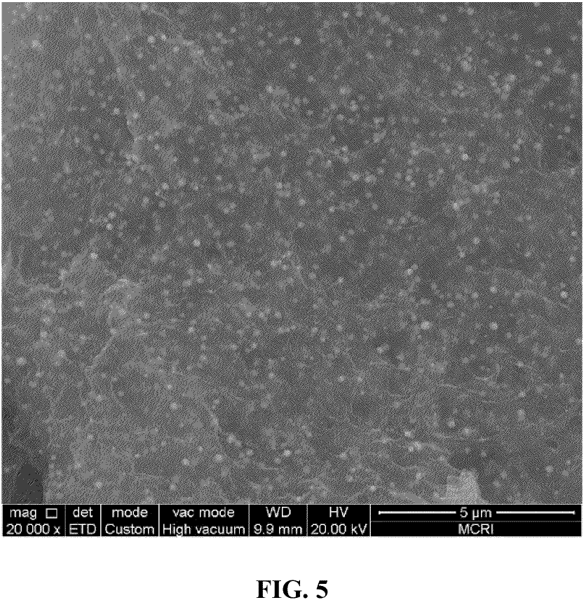

FIG. 5 is the SEM image of the obtained graphene-supported platinum nanoparticle composite powder, with a scale of 5 µm, and a magnification of 20000. As can be seen from FIG. 5, the platinum nanoparticles have uniform particle size, and are evenly distributed between layers of the graphene, and the graphene is in a transparent layered structure with wrinkles at the edges.

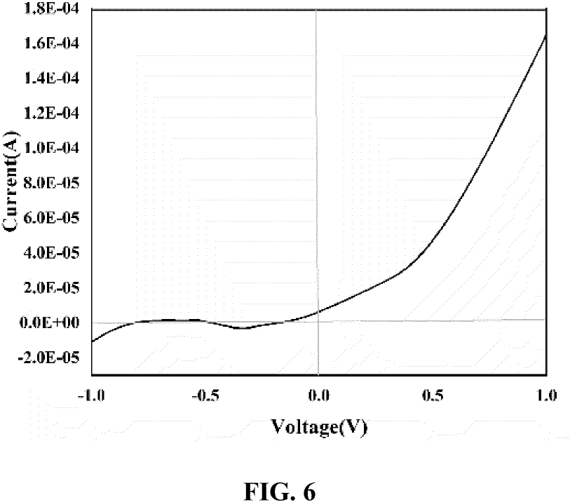

FIG. 6 shows the I-V characteristic curve of the Schottky device. As can be seen from FIG. 6, the current at the forward voltage of 1 V is 1.65E-4, the Schottky barrier height is 0.633 eV, and the ideality factor is 2.89.

### Example 3

The example was performed according to Example 2, except that the amount of chloroplatinic acid hexahydrate in step (2) was 150 mg, and finally the graphene-supported platinum nanoparticle composite powder was prepared. A Schottky device was prepared from the obtained graphene-supported platinum nanoparticle composite powder according to step (5) in Example 2.

The obtained composite powder was observed by SEM, and the I-V characteristic curve of the Schottky device was tested according to step (6) in Example 2. As can be seen from the results, the particle size of platinum nanoparticles is not uniform, a slight agglomeration of graphene is present, and there are wrinkles at the edges. The current at the forward voltage of 1 V is 9.48E-5, the Schottky barrier height is 0.628 eV, and the ideal The factor is 2.04.

### Example 4

The example was performed according to Example 1, except that the amount of chloroauric acid was 50 mg, and finally a graphene-supported aurum nanoparticle composite powder was obtained. A Schottky device was prepared from the obtained graphene-supported aurum nanoparticle composite powder according to step (5) in Example 1.

The obtained composite powder was observed by SEM, and the I-V characteristic curve of the Schottky device was tested according to step (6) in Example 1. As can be seen from the results, aurum nanoparticles are distributed on the surface and between layers of graphene, there are wrinkles at the edges, and agglomerated aurum nanoparticles are present at wrinkles of the graphene. Because the amount of chloroauric acid is less, the amount of aurum nanoparticles in the composite powder is less. Therefore, there is a slight agglomeration of graphene sheets. The I-V characteristic curve shows that the current at the forward voltage of 1 V (being 1.27E-4) is slightly lower than that of Example 1, and the Schottky barrier height (being 0.608 eV) is slightly lower than that of Example 1, and the ideality factor is 1.15.

### Example 5

The example was performed according to Example 2, except that the amount of chloroplatinic acid hexahydrate in step (2) was 10 mg, and finally a graphene-supported platinum nanoparticle composite powder was obtained. A Schottky device was prepared from the obtained graphene-supported platinum nanoparticle composite powder according to step (5) in Example 2.

The obtained composite powder was observed by SEM, and the I-V characteristic curve of the Schottky device was tested according to step (6) in Example 2. As can be seen from the results, because the amount of chloroplatinic acid is less, the amount of platinum nanoparticles in the final composite powder is less, and there is a slight agglomeration of graphene, and there are wrinkles at edges. As can be seen from the I-V characteristic curve, the current at a forward voltage of 1 V is 6.57 E-5, which is lower than that of Examples 2-3, the Schottky barrier height is 0.627 eV, which is slightly lower than that of Examples 2-3, and the ideality factor is 1.63.

The above are only the preferred embodiments of the present disclosure. It should be pointed out that for those skilled in the art, without departing from the principles of the present disclosure, several improvements and modifications could be made. They should fall within the scope of the present disclosure.

1. A method for preparing a graphene-supported noble-metal composite powder, the method comprising:
mixing a graphene oxide solution, a solution of a noble metal precursor, and a reducing agent to obtain a mixed solution, the noble metal precursor comprising a noble metal present in the form of ions; and
subjecting the mixed solution to a hydrothermal reduction reaction to obtain the graphene-supported noble-metal composite powder.

2. The method as claimed in claim 1, wherein the graphene oxide solution has a concentration of 1-2 mg/mL.

3. The method as claimed in claim 1, wherein:
the noble metal in the graphene-supported noble-metal composite powder is selected from a group consisting of aurum and platinum; and
a mass ratio of the graphene oxide in the graphene oxide solution to the noble metal precursor in the solution of the noble metal precursor is in the range of 5:1 to 1:3.

4. The method as claimed in claim 1, wherein the noble metal precursor is at least one selected from a group consisting of chloroauric acid and chloroplatinic acid.

5. The method as claimed in claim 1, wherein the reducing agent comprises at least one selected from a group consisting of ascorbic acid, hydrazine hydrate, and sodium borohydride.

6. The method as claimed in claim 1, wherein mixing the graphene oxide solution, the solution of the noble metal precursor, and the reducing agent is performed by:
adding the solution of the noble metal precursor to the graphene oxide solution, and subjecting a resulting mixture to a first ultrasonic oscillation; and
adding ascorbic acid thereto and subjecting a resulting mixture to a second ultrasonic oscillation to obtain a mixed solution.

7. The method as claimed in claim 1, wherein the hydrothermal reduction reaction is performed at a temperature of 130-180° C. for 10-14 hours.

8. A graphene-supported noble-metal composite powder, comprising graphene and noble metal nanoparticles supported on a surface and between layers of the graphene, the noble metal nanoparticles in the graphene-supported noble-metal composite powder accounting for 5-60 wt%, wherein
the graphene-supported noble-metal composite powder is prepared by a method comprising:
mixing a graphene oxide solution, a solution of a noble metal precursor, and a reducing agent, to obtain a mixed solution, the noble metal precursor comprising a noble metal present in the form of ions; and
subjecting the mixed solution to a hydrothermal reduction reaction, to obtain the graphene-supported noble-metal composite powder.

9. A Schottky device comprising:
a semiconductor substrate; and
a coating of a composite powder on a surface of the semiconductor substrate, the composite powder being the graphene-supported noble-metal composite powder as claimed in claim 8.

10. The Schottky device as claimed in claim 9, wherein the composite powder on the surface of the semiconductor substrate is present in an amount of 10-20 mg/cm².

11. A method for preparing the Schottky device as claimed in claim 9, comprising:
dispersing the graphene-supported noble-metal composite powder as claimed in claim 8 in an alcohol solvent, to obtain a composite powder dispersion; and
applying the composite powder dispersion to a surface of a semiconductor, and drying, to obtain the Schottky device.

12. The method as claimed in claim 11, wherein the alcohol solvent is anhydrous ethanol.

13. The method as claimed in claim 11, wherein the composite powder dispersion has a composite powder concentration of 2-8 mg/mL.

14. The method as claimed in claim 3, wherein the noble metal precursor is at least one selected from a group consisting of chloroauric acid and chloroplatinic acid.

15. The method as claimed in claim 3, wherein mixing the graphene oxide solution, the solution of the noble metal precursor, and the reducing agent is performed by
adding the solution of the noble metal precursor to the graphene oxide solution, and subjecting a resulting mixture to a first ultrasonic oscillation; and
adding ascorbic acid thereto, and subjecting a resulting mixture to a second ultrasonic oscillation, to obtain a mixed solution.

16. The method as claimed in claim 5, wherein mixing the graphene oxide solution, the solution of the noble metal precursor, and the reducing agent is performed by
adding the solution of the noble metal precursor to the graphene oxide solution, and subjecting a resulting mixture to a first ultrasonic oscillation; and
adding ascorbic acid thereto, and subjecting a resulting mixture to a second ultrasonic oscillation, to obtain a mixed solution.

17. The graphene-supported noble-metal composite powder as claimed in claim 8, wherein:
the noble metal in the graphene-supported noble-metal composite powder is selected from a group consisting of aurum and platinum; and
a mass ratio of the graphene oxide in the graphene oxide solution to the noble metal precursor in the solution of the noble metal precursor is in the range of 5:1 to 1:3.

18. The graphene-supported noble-metal composite powder as claimed in claim 8, wherein the noble metal precursor is at least one selected from a group consisting of chloroauric acid and chloroplatinic acid.

19. The graphene-supported noble-metal composite powder as claimed in claim 8, wherein the reducing agent comprises at least one selected from a group consisting of ascorbic acid, hydrazine hydrate, and sodium borohydride.

20. The method as claimed in claim 11, wherein the composite powder on the surface of the semiconductor substrate is present in an amount of 10-20 mg/cm².
